(19) United States
(12) Patent Application Publication
(10) Pub. No.: US 2008/0009128 A1
(43) Pub. Date: Jan. 10, 2008

(54) Buried pattern substrate and manufacturing method thereof

(75) Inventors: Shuhichi Okabe, Suwon (KR); Myung-Sam Kang, Suwon-si (KR); Jung-Hyun Park, Suwon-si (KR); Hoe-Ku Jung, Daejeon (KR); Ji-Eun Kim, Gwangmyeong-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 11/708,339

(22) Filed: Feb. 21, 2007

(30) Foreign Application Priority Data
Jul. 6, 2006 (KR) 10-2006-0063637

(51) Int. Cl. H01L 21/44

(52) U.S. Cl. 438/597

(57) ABSTRACT

A buried pattern substrate and a manufacturing method thereof are disclosed. A method of manufacturing a buried pattern substrate having a circuit pattern formed on a surface, in which the circuit pattern is connected electrically by a stud bump, includes (a) forming the circuit pattern and the stud bump by depositing a plating layer selectively on a seed layer of a carrier film, where the seed layer is laminated on a surface of the carrier film, (b) laminating and pressing the carrier film on an insulation layer such that the circuit pattern and the stud bump face the insulation layer, and (c) removing the carrier film and the seed layer, allows the circuit interconnection to be realized using a copper (Cu) stud bump, so that a drilling process for interconnection is unnecessary, the degree of freedom for circuit design is improved, a via land is made unnecessary and the size of a via is small, to allow higher density in a circuit.

### CROSS-REFERENCE TO RELATED APPLICATIONS

This application claims the benefit of Korean Patent Application No. 10-2006-0063637 filed with the Korean Intellectual Property Office on Jul. 6, 2006, the disclosure of which is incorporated herein by reference in its entirety.

### BACKGROUND

1. Technical Field

The present invention relates to a buried pattern substrate and manufacturing method thereof.

2. Description of the Related Art

With developments in the electronics industry, there is a demand for high performance and function, high density and miniaturization for electronic components, and high density substrates for surface mounting of electronic components such as SIP (System in package), 3D package, etc. are on the rise. As such, in order to cope with the trend of higher density and thinner substrates, high density connection between circuit pattern layers is required.

For electrical interconnection in a multi layer circuit pattern substrate, such techniques are used as plating, filling conductive material in via holes by printing metal paste, and the so-called B2it (Buried bump interconnection technology), which is interconnection by means of conically shaped paste, etc.

The plating is a method of processing a via hole such as a PTH (Plated through hole) and a BVH (Blind via hole) penetrating the circuit pattern layers of a multi layer circuit pattern substrate, and then plating the inside of the via hole with copper or filling in a copper plated layer in the via hole, to realize the interconnection.

In the filling of the metal paste, after processing a via hole by using laser, the interconnection is realized by filling copper (Cu) paste, etc. in the via hole. This technology enables the interlayer electrical signal to be connected by arraying multiple core layers, in which the interconnections have been realized, and attaching to the core layer by heating and collectively pressing together.

The ‘B2it’ is a method of forming paste studs by printing and hardening special conductive paste in a conical shape on a copper plate, and then making them penetrate the insulation layer, and heating and pressing, to realize the interconnections.

However, the conventional technologies described above have limitations in high density interconnection, and cannot be applied as a complete production technology.

### SUMMARY

Aspects of the present invention provide a buried pattern substrate and a manufacturing method thereof that can improve the degree of freedom of circuit design and realize higher density and thinner circuits by increasing the density of the interconnection between circuit pattern layers in a multi layer printed circuit board.

One aspect of the present invention provides a method of manufacturing a buried pattern substrate having a circuit pattern formed on a surface, where the circuit pattern is connected electrically by a stud bump. The method includes (a) forming the circuit pattern and the stud bump by depositing a plating layer selectively on a seed layer of a carrier film, in which the seed layer is laminated on a surface of the carrier film, (b) laminating and pressing the carrier film on an insulation layer such that the circuit pattern and the stud bump face the insulation layer, and (c) removing the carrier film and the seed layer.

The circuit pattern may be formed by, (a1) laminating a first photoresist on the seed layer and selectively removing a part of the first photoresist corresponding to the circuit pattern, and (a2) depositing a plating layer onto the seed layer.

The stud bump may be formed by depositing a plating layer to a part of the circuit pattern, or by (a3) laminating a second photoresist to cover the circuit pattern and the first photoresist, and selectively removing a part of the second photoresist corresponding to a location where the stud bump is to be formed, and (a4) depositing a plating layer onto the seed layer by supplying electricity.

The method may further comprise removing the first photoresist and the second photoresist between the operation (a4) and the operation (b). The operation (a4) may comprise further plating a metallic layer of a material different from that of the seed layer in an end portion of the stud bump by supplying electricity to the seed layer.

The stud bump may be formed by protruding a plating layer of a same material as that of the seed layer from the seed layer, where a metallic layer of a different material from that of the seed layer is deposited in an end portion of the stud bump.

The plating layer may comprise copper (Cu), and the metallic layer may comprise one or more of tin (Sn) and nickel (Ni).

The operation (a) may comprise (d) forming the stud bump in two of the carrier films respectively, and the operation (b) may comprise (e) laminating and pressing the two carrier films on both faces of the insulation layer such that the stud bumps face each other, and connecting the stud bumps electrically with each other. The operation (d) may comprise forming the circuit pattern in the two carrier films respectively.

Another aspect of the present invention provides a buried pattern substrate comprising an insulation layer, a circuit pattern buried in the insulation layer such that a part thereof is exposed at a surface of the insulation layer, and a stud bump buried in the insulation layer such that one end portion is exposed at one surface of the insulation layer, and such that the other end portion is exposed at the other surface of the insulation layer.

The circuit pattern may be buried in each of the two surfaces of the insulation layer.

The stud bump may be formed by connecting a first stud bump and a second stud bump, in which the first bump may be buried in the insulation layer such that one end portion is exposed at one surface of the insulation layer, and the second stud bump may be buried in the insulation layer such that one end portion is exposed at the other surface of the insulation layer.

The locations of the first stud bump and the second stud bump may be symmetrical with respect to the insulation layer

The first stud bump may comprise a body, one end portion exposed at one surface of the insulation layer, and the other end portion facing the second stud bump, where the other end portion of the first stud bump may comprise a metal of a different material from that of the body of the first stud bump.

The body of the first stud bump may comprise copper (Cu), and the other end portion of the first stud bump may comprise one or more of tin (Sn) and nickel (Ni).

Additional aspects and advantages of the present invention will become apparent and more readily appreciated from the following description, including the appended drawings and claims, or may be learned by practice of the invention.

### BRIEF DESCRIPTION OF THE DRAWINGS

FIG. 1 is a flow chart illustrating an embodiment of a manufacturing method of a buried pattern substrate according to the present invention.

FIG. 2 is a flow diagram illustrating an embodiment of a manufacturing process of a buried pattern substrate according to the present invention.

FIG. 3 is a cross-sectional view illustrating the first disclosed embodiment of a buried pattern substrate according to the present invention.

FIG. 4 is a cross-sectional view illustrating the second disclosed embodiment of a buried pattern substrate according to the present invention.

FIG. 5 is a cross-sectional view illustrating the third disclosed embodiment of a buried pattern substrate according to the present invention.

### DETAILED DESCRIPTION

Embodiments of the a buried pattern substrate and a manufacturing method thereof according to the invention will be described below in more detail with reference to the accompanying drawings. In the description with reference to the accompanying drawings, those components are rendered the same reference number that are the same or are in correspondence regardless of the figure number, and redundant explanations are omitted.

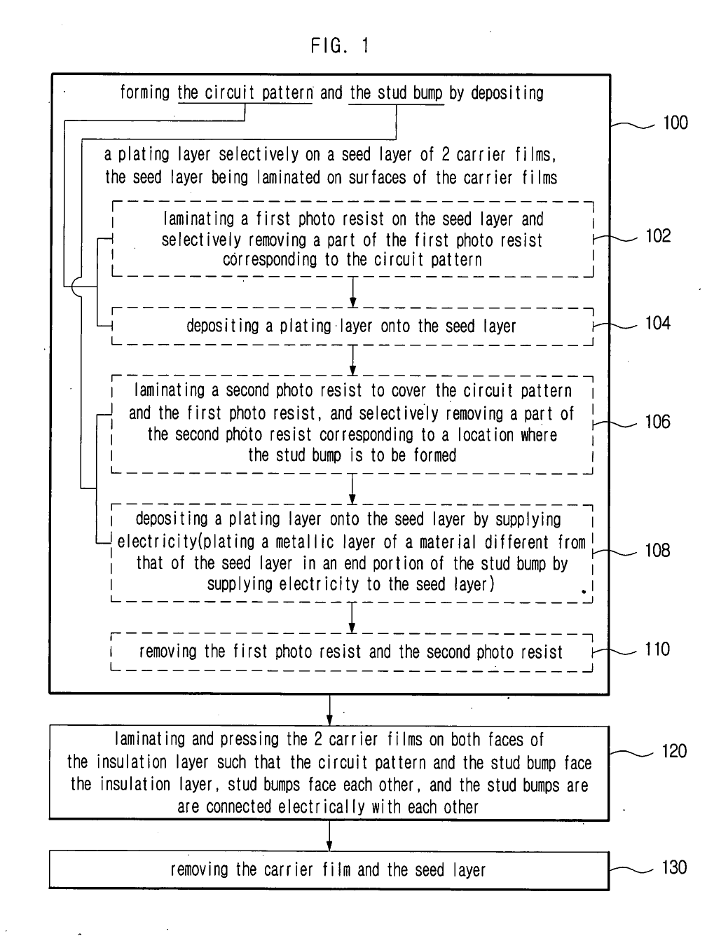

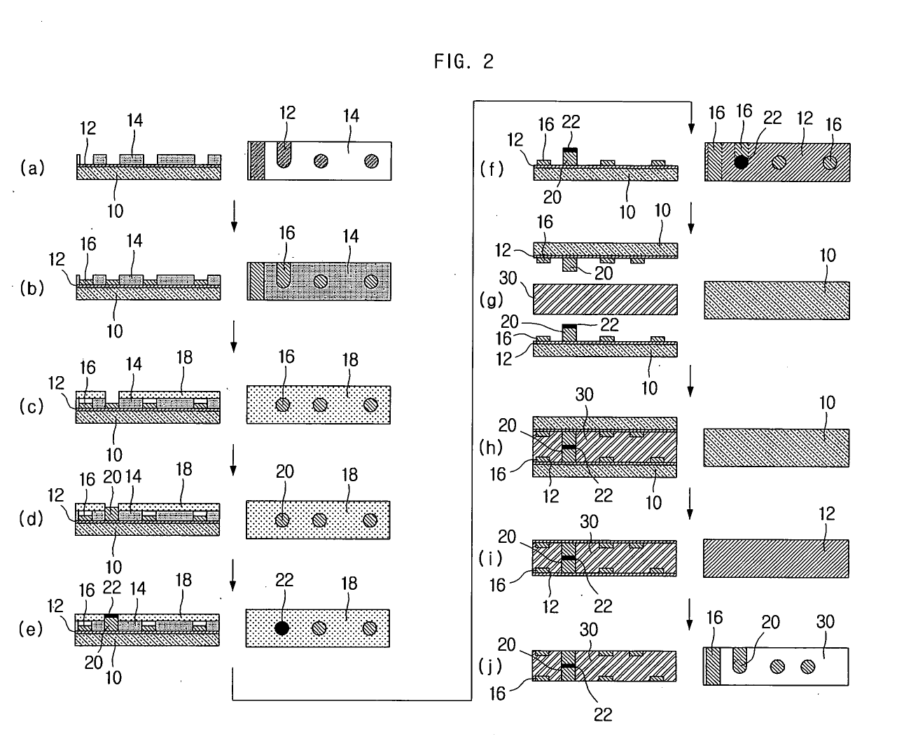

FIG. 1 is a flow chart illustrating an embodiment of a manufacturing method of a buried pattern substrate according to the present invention, and FIG. 2 is a flow, diagram illustrating an embodiment of a manufacturing process of a buried pattern substrate according to the present invention. Referring to FIG. 2, a carrier film 10, a seed layer 12, photoresists 14, 18, a circuit pattern 16, a stud bump 20, a metallic layer 22, and an insulation layer 30 are illustrated.

FIG. 2 represents a manufacturing process of a buried pattern substrate according to the present embodiment, and illustrates the cross-sectional view of the substrate on the left and the plan view on the right for each step.

The present embodiment is characterized, in the process of forming a buried pattern, by further forming the stud bump 20 that protrudes in the shape of a bump as a part of the circuit pattern 16, and using this to realize high density electrical interconnection, whereby the degree of freedom of circuit design is improved and a higher density and thinner circuit is realized.

In the so-called ‘buried pattern substrate’ according to the present embodiment, in which the circuit pattern 16 is buried in a surface, in order to manufacture a printed circuit board that realizes the electrical interconnection of the circuit pattern 16 by means of the stud bump 20, firstly, the seed layer 12 is laminated on a surface of the carrier film 10 by electroless plating, etc., and the embossed circuit pattern 16 protruding from the seed layer 12 is formed by electro plating the seed layer 12 selectively. In this step, as a part of the circuit pattern 16 or separate from the circuit pattern 16, the stud bump 20 protruding more than the circuit pattern 16 is formed as well, as a pathway for electrical interconnection (100). In forming the circuit pattern 16, after laminating the photoresist 14 on the seed layer 12 laminated on the surface of the carrier film 10 and removing by selective exposure and development only the parts where the circuit pattern 16 is to be formed (102) as in FIG. 2(a), an electro plated layer is added by supplying electricity to the seed layer 12 (104), as in FIG. 2(b). In this manner, the embossed circuit pattern 16 is formed on the seed layer 12.

In the case of forming only a buried pattern, the photoresist 14 is peeled after forming the circuit pattern 16, but in the present embodiment, the stud bump 20 is formed by adding a plated layer to parts of the circuit pattern 16. In forming the circuit pattern 16, after adding the plated layer to the parts where the stud bump 20 is to be formed, electro plating is performed again on the parts where the stud bump 20 is to be formed.

That is, after forming the circuit pattern 16 by adding a plated layer to the part where the photoresist 14 is removed selectively, the photoresist 18 is laminated again and removed by selective exposure and development only from the parts where the stud bump 20 will be formed (106) as in FIG. 2(c), and then, the electro plated layer is added by supplying electricity to the seed layer 12 (108), as in FIG. 2(d). In this manner, the stud bump 20 protruding more than the circuit pattern 16 is formed.

In the case that the copper seed layer 12 is added by electroless copper plating to the carrier film 10, the circuit pattern 16 and the stud bump 20 are formed by electro copper plating, so that all of the seed layer 12, the circuit pattern 16 and stud bump 20 consist of copper (Cu).

In this case, by supplying electricity to the seed layer 12 before peeling the photoresist 18 laminated for forming the stud bump 20, as in FIG. 2(e), different kinds of the metallic layer 22 such as tin (Sn), nickel (Ni), etc. can further be plated to an end portion of the stud bump 20. Such plating of the end portion of the stud bump 20 with a different kind of metal, as described in the following, lowers the connection temperature in the process of connecting the stud bumps 20 with each other, to allow easier connection.

After forming the circuit pattern 16 and the stud bump 20 and plating an end portion of the stud bump 20 with a different kind of metal, the photoresists 14, 18 laminated for selective plating are peeled and removed (110), as in FIG. 2(f).

Next, the carrier film 10 on which the circuit pattern 16 and the stud bump 20 are protruded is laminated on the seed layer 12 on the insulation layer 30 (120). That is, the carrier film 10 is pressed onto the insulation layer 30 such that the circuit pattern 16 and the stud bump 20 face the insulation layer 30, whereby the circuit pattern 16 and the stud bump 20 are buried in the insulation layer 30.

In order to realize electrical interconnection between circuits using the stud bumps 20, two carrier films 10 are laminated where the stud bumps 20 are formed on the both faces of the insulation layer 30 respectively as in FIG. 2(g), and are pressed as in FIG. 2(h), to enable the stud bumps 20 to be connected with each other. In this process, the stud bumps 20 formed on the two carrier films 10 are located to be opposite each other.

As described above, due to the different kinds of the metallic layer 22 plated on the end portion of the stud bump 20, the connection can be made easy by lowering the connection temperature in the process of connecting the stud bumps 20 with each other.

After burying the circuit pattern 16 and the stud bump 20 in the insulation layer 30, and making the electrical connection by connecting the stud bumps 20 each other, peel the carrier film 10 is peeled as in FIG. 2(i), and the seed layer 12 is removed as in FIG. 2(j) by etching, etc. (130). In this manner, the manufacture of a buried pattern substrate in which interconnection is realized by the buried pattern and the stud bumps 20 is completed.

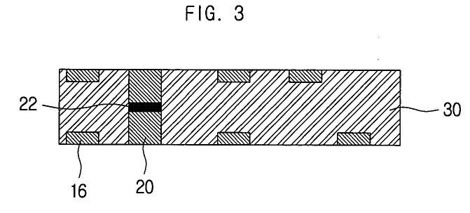

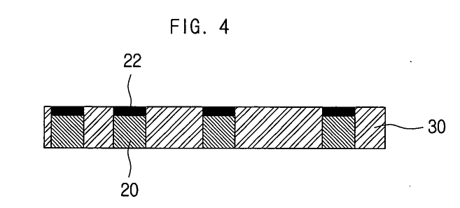

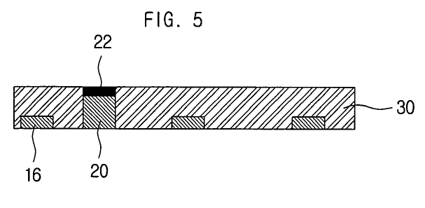

FIG. 3 is a cross-sectional view illustrating the first embodiment of a buried pattern substrate according to the present invention, FIG. 4 is a cross-sectional view illustrating the second embodiment of a buried pattern substrate according to the present invention, and FIG. 5 is a cross-sectional view illustrating the third embodiment of a buried pattern substrate according to the present invention. Referring to FIG. 3 to FIG. 5, circuit patterns 16, stud bumps 20, a metallic layer 22, and an insulation layer 30 are illustrated.

Conventional interconnection methods have limitations in high density interconnection so that it was hard to design high density circuits, whereas the interconnection using stud bumps 20 in the substrate where the buried circuit pattern 16 is formed, according to the manufacturing method of a buried pattern substrate described above, enables the manufacturing of higher density and thinner circuits.

FIG. 3 illustrates the structure of the buried pattern substrate manufactured by the manufacturing method of a buried pattern substrate described above. That is, the buried pattern substrate according to the present embodiment consists of the buried pattern buried in the insulation layer 30 and having a surface exposed at the surface of the insulation layer 30, and the stud bump 20 penetrating the insulation layer 30, which has surfaces exposed at both faces of the insulation layer 30, and which plays the role of an electrical pathway between circuit layers.

As described above in the manufacturing process of a buried pattern substrate, because the circuit pattern 16 formed protruded on the carrier film 10 is pressed to both faces of the insulation layer 30, the circuit pattern 16 is buried in both faces of the insulation layer 30 respectively. In the carrier film 10, not only the circuit pattern 16 but also the stud bump 20 is formed protruded, so that the electrical pathway between circuit layers can be formed with the two stud bumps 20 buried in both faces of the insulation layer 30 and connecting with each other. That is, the two stud bumps 20 are connected buried in locations symmetrical to each other in both faces with respect to the insulation layer 30.

However, the carrier film 10 where the circuit pattern 16 and the stud bump 20 are formed in both faces of the insulation layer 30 does not necessarily have to be pressed and laminated as illustrated in FIG. 3, and instead, the buried pattern and the interconnection can be realized by pressing the carrier film 10 to only one side of the insulation layer 30 as in FIG. 5. In this case, in order for the stud bump 20 to function as the pathway for interconnection, it is preferable that the protruded height of the stud bump 20 be in correspondence with the thickness of the insulation layer 30.

The stud bumps 20 of the present embodiment function as the pathway which realizes the electrical connection between circuit layers, so by adding them independently to the conventional process of forming a circuit pattern, it can be used in realizing electrical connection between circuit layers. That is, the embodiment of FIG. 4 illustrates the example of forming only the stud bumps 20 on the carrier film 10, and then burying the stud bumps 20 in the insulation layer 30 to realize the interconnection. In this case, in order for the stud bumps 20 to function as the pathway for interconnection, it is preferable that the protruded height of the stud bump 20 be in correspondence with the thickness of the insulation layer 30.

The stud bumps 20 of the present embodiment are formed by laminating the seed layer 12 on the carrier film 10 and plating the part selectively, and thus the stud bumps 20 can easily be formed without additional processes by performing further plating before peeling the photoresist 14 after the process of forming the circuit pattern 16. That is, by adding the forming process of the stud bumps 20 of the present embodiment in the forming process of a buried pattern, the electrical connection between circuit layers can be easily realized.

As described above, by plating a different kind of the metallic layer 22 on an end portion of the stud bump 20, the connection temperature of the process of connecting the stud bumps 20 with each other is lowered and the connection become easy, so when grouping the stud bump 20 into a body, one end portion at a surface of the insulation layer 30 and the other end portion connected to another stud bump 20, further plating may be performed at the other end portion of the stud bump 20, on the body and the different kind of the metallic layer 22.

In the case of forming the circuit pattern 16 and the stud bumps 20 by copper plating, it is preferable to plate with tin (Sn), nickel (Ni), etc. in the end portions of the stud bumps 20.

According to the present invention comprised as above, the circuit interconnection is realized using a copper (Cu) stud bump, so that a drilling process for interconnection is unnecessary, the degree of freedom is improved in circuit design, a via land is rendered unnecessary and the size of a via is small, to allow higher density in a circuit.

Also, a circuit pattern is formed by burying in an insulation layer, so that the thickness of a substrate can be made thin, the contact area between a circuit pattern and an insulation layer resin is large and the adhesive strength is excellent, and the reliability is improved for ion-migration.

Also, in the process of joining stud bumps, the end portion of a stud is plated with a metal of a different kind such as tin (Sn) and nickel (Ni), and the connection temperature in the connection of a stud can be lowered allowing easier connection.

While the above description has pointed out novel features of the invention as applied to various embodiments, the skilled person will understand that various omissions, substitutions, and changes in the form and details of the device or process illustrated may be made without departing from the scope of the invention. Therefore, the scope of the invention is defined by the appended claims rather than by the foregoing description. All variations coming within the meaning and range of equivalency of the claims are embraced within their scope.

What is claimed is:

1. A method of manufacturing a buried pattern substrate having a circuit pattern formed on a surface, wherein the circuit pattern is connected electrically by a stud bump, the method comprising:
(a) forming the circuit pattern and the stud bump by depositing a plating layer selectively on a seed layer of a carrier film, the seed layer being laminated on a surface of the carrier film;
(b) laminating and pressing the carrier film on an insulation layer such that the circuit pattern and the stud bump face the insulation layer; and
(c) removing the carrier film and the seed layer.

2. The method of claim 1, wherein the circuit pattern is formed by,
(a1) laminating a first photoresist on the seed layer and selectively removing a part of the first photoresist corresponding to the circuit pattern; and
(a2) depositing a plating layer onto the seed layer.

3. The method of claim 2, wherein the stud bump is formed by depositing a plating layer to a part of the circuit pattern.

4. The method of claim 3, wherein the stud bump is formed by:
(a3) laminating a second photoresist to cover the circuit pattern and the first photoresist, and selectively removing a part of the second photoresist corresponding to a location where the stud bump is to be formed; and
(a4) depositing a plating layer onto the seed layer by supplying electricity.

5. The method of claim 4, further comprising removing the first photoresist and the second photoresist between the operation (a4) and the operation (b).

6. The method of claim 4, wherein the operation (a4) comprises further plating a metallic layer of a material different from that of the seed layer in an end portion of the stud bump by supplying electricity to the seed layer.

7. The method of claim 1, wherein the stud bump is formed by protruding a plating layer of a same material as that of the seed layer from the seed layer, and wherein a metallic layer of a different material from that of the seed layer is deposited in an end portion of the stud bump.

8. The method of claim 6 or claim 7, wherein the plating layer comprises copper (Cu), and the metallic layer comprises one or more of tin (Sn) and nickel (Ni).

9. The method of claim 1, wherein the operation (a) comprises:
(d) forming the stud bump in two of the carrier films respectively;
and the operation (b) comprises:
(e) laminating and pressing the two carrier films on both faces of the insulation layer such that the stud bumps face each other, and connecting the stud bumps electrically with each other.

10. The method of claim 9, wherein the operation (d) comprises forming the circuit pattern in the two carrier films respectively.

11. A buried pattern substrate comprising:
an insulation layer;
a circuit pattern buried in the insulation layer such that a part thereof is exposed at a surface of the insulation layer; and
a stud bump buried in the insulation layer such that one end portion is exposed at one surface of the insulation layer, and such that the other end portion is exposed at the other surface of the insulation layer.

12. The buried pattern substrate of claim 11, wherein the circuit pattern is buried in each of the two surfaces of the insulation layer.

13. The buried pattern substrate of claim 11, wherein the stud bump is formed by connecting a first stud bump and a second stud bump, the first bump being buried in the insulation layer such that one end portion is exposed at one surface of the insulation layer, and the second stud bump being buried in the insulation layer such that one end portion is exposed at the other surface of the insulation layer.

14. The buried pattern substrate of claim 13, wherein locations of the first stud bump and the second stud bump are symmetrical with respect to the insulation layer

15. The buried pattern substrate of claim 13, wherein the first stud bump comprises a body, one end portion exposed at one surface of the insulation layer, and the other end portion facing the second stud bump, wherein the other end portion of the first stud bump comprises a metal of a different material from that of the body of the first stud bump.

16. The buried pattern substrate of claim 15, wherein the body of the first stud bump comprises copper (Cu), and the other end portion of the first stud bump comprises one or more of tin (Sn) and nickel (Ni).
